(19) United States
(12) Patent Application Publication
(10) Pub. No.: US 2017/0110055 A1
(43) Pub. Date: Apr. 20, 2017

(54) PIXEL CIRCUIT, DRIVING METHOD THEREOF AND RELATED DEVICES

(71) Applicant: BOE TECHNOLOGY GROUP CO., LTD., Beijing (CN)

(72) Inventors: Yongqian LI, Beijing (CN); Longyan WANG, Beijing (CN); Quanhu LI, Beijing (CN); Jingwen YIN, Beijing (CN); Baoxia ZHANG, Beijing (CN); Cuili GAI, Beijing (CN); Kun CAO, Beijing (CN); Zhongyuan WU, Beijing (CN)

(73) Assignee: BOE TECHNOLOGY GROUP CO., LTD., Beijing (CN)

(21) Appl. No.: 15/122,390

(22) PCT Filed: Jul. 20, 2015
(86) PCT No.: PCT/CN2015/084416

§ 371 Date: Aug. 29, 2016

(30) Foreign Application Priority Data
Apr. 27, 2015 (CN) 201510206426.7

(51) Int. Cl. G09G 3/3258; H01L 51/50; G09G 3/325; H01L 27/32; G09G 3/3266; G09G 3/3291

(52) U.S. Cl. CPC G09G 3/3258; G09G 3/3266; G09G 3/3291; G09G 3/325; H01L 27/3265; H01L 27/3276; H01L 51/5012; G09G 2300/0809; G09G 2300/043

(57) ABSTRACT

The present disclosure relates to a pixel circuit, a driving method thereof and related devices. The pixel circuit comprises: a reset compensation module, a data writing module, a storage module and a driving transistor. With the cooperation of each module, the pixel circuit can compensate shift of a threshold voltage for a driving transistor by storing the threshold voltage for the driving transistor in the storage module. Therefore, when the source of the driving transistor in the pixel circuit is connected with a light emitting device for driving it to emit light for display, the driving current of the driving transistor for driving the light emitting device to emit light will be only associated with the voltage of the data signal, but not the threshold voltage for the driving transistor. In this way, influence of the threshold voltage of the driving transistor on the light emitting device will be avoided.

### RELATED APPLICATIONS

The present application claims the benefit of Chinese Patent Application No. 201510206426.7, filed on Apr. 27, 2015, the entire disclosure of which is incorporated herein by reference.

### FIELD

The present disclosure relates to the technical field of organic electroluminescence, and in particular to a pixel circuit, a driving method thereof and related devices.

### BACKGROUND ART

Organic light emitting diodes (OLED) are one of the focuses in the field of flat panel display studies today. As compared with liquid crystal displays, OLEDs has advantages such as low energy consumption, low production cost, self-luminescence, wide view angle, and fast response. At present, in the field of plat panel display such as handset, PDA and digital camera, OLEDs have begun replacing the traditional liquid crystal displays (LCD). For an OLED, the pixel circuit design is a core technology and hence the research thereon is very important.

Different from an LCD whose luminance is controlled by a stable voltage, OLED is driven by a current, so it requires a stable current for controlling its light emission. As a result of technique process, device aging and so on, there is unevenness in a threshold voltage Vₜₕ for a driving transistor of the pixel circuit. This can easily cause the current flowing through each pixel point OLED to change such that the display luminance is uneven, which influences the display effect of the entire image. Moreover, since the current is associated with a source (i.e., a supply voltage) of the driving transistor, IR Drop will also result in current difference in different regions, which leads to luminance unevenness of the OLED device in different regions.

For example, detailed explanations are given with reference to a 2T1C pixel circuit in the prior art. As shown in FIG. 1, the 2T1C pixel circuit comprises a driving transistor T2, a switching transistor T1 and a storage capacitor Cs. When a scanning line Scan selects a certain row, the scanning line Scan inputs a low level signal. At this point, the P-type switching transistor T1 is switched on and the voltage of a data line Data is written into the storage capacitor Cs. When the scanning of the row is completed, the signal input by the scanning line Scan turns into a high level. At this point, the P-type switching transistor T1 is switched off and a gate voltage stored in the storage capacitor Cs drives the transistor T2 to generate a current for driving the OLED, thus ensuring that the OLED can continuously emit light within a frame. In this case, the formula for a saturation current of the driving transistor T2 is I_{OLED}=K(V_{SG}−Vₜₕ)². As mentioned, the threshold voltage Vₜₕ for the driving transistor T2 will shift due to technique process, device aging and so on. This will easily cause the current flowing through each OLED to change with the threshold voltage Vₜₕ for the driving transistor, which leads to unevenness of the image luminance.

### SUMMARY

To this end, embodiments of the present disclosure provide a pixel circuit, an organic electroluminescent display panel and a display device, for improving evenness of image luminance in a display region of a display device.

Therefore, the embodiments of the present disclosure provide a pixel circuit, comprising: a reset compensation module, a data writing module, a storage module and a driving transistor.

A drain of the driving transistor is connected with a first reference signal terminal; a gate thereof is connected with a first end of the storage module, a first output end of the reset compensation module and an output end of the data writing module respectively; and a source thereof is connected with a second output end of the reset compensation module and a second end of the storage module respectively.

A first input end of the reset compensation module is used for receiving a first control signal, a second input end thereof is used for receiving a second control signal, a third input end thereof is used for receiving a reset signal and a fourth input end thereof is used for receiving an initialization signal. The reset compensation module is further configured for: during a first stage, providing the reset signal to the gate of the driving transistor and the initialization signal to the source of the driving transistor under the control of the first control signal and the second control signal; and during a second stage, storing a threshold voltage for the driving transistor in the storage module under the control of the first control signal.

A first input end of the data writing module is used for receiving a third control signal and a second input end thereof is used for receiving a data signal. The data writing module is further configured for: during a third stage, writing the data signal into the first end of the storage module under the control of the third control signal.

In a possible implementation, the pixel circuit provided by the embodiments of the present disclosure further comprises a light emitting device. One end of the light emitting device is connected with the source of the driving transistor, and the other end thereof is connected with a second reference signal terminal. The driving transistor is further configured for: during a fourth stage, driving the light emitting device to emit light under the control of the storage module.

In a possible implementation, in the pixel circuit provided by the embodiments of the present disclosure, the reset compensation module comprises: a first switching transistor and a second switching transistor. A gate of the first switching transistor is the first input end of the reset compensation module, a source thereof is the third input end of the reset compensation module and a drain thereof is the first output end of the reset compensation module. A gate of the second switching transistor is the second input end of the reset compensation module, a source thereof is the fourth input end of the reset compensation module and a drain thereof is the second output end of the reset compensation module.

In a possible implementation, in the pixel circuit provided by the embodiments of the present disclosure, the data writing module comprises: a third switching transistor. A gate of the third switching transistor is the first input end of the data writing module, a source thereof is the second input end of the data writing module and a drain thereof is the output end of the data writing module.

In a possible implementation, in the pixel circuit provided by the embodiments of the present disclosure, the storage module is a capacitor. A first electrode plate of the capacitor is the first end of the storage module, and a second electrode plate thereof is the second end of the is storage module.

Optionally, in the pixel circuit provided by the embodiments of the present disclosure, the driving transistor is an N-type transistor.

Optionally, in order to simplify the manufacture process, in the pixel circuit provided by the embodiments of the present disclosure, the switching transistors are all P-type transistors or N-type transistors.

Correspondingly, the embodiments of the present disclosure further provide a driving method for any of the above pixel circuits, comprising: during a first stage, providing, by the reset compensation module, the reset signal to the gate of the driving transistor and the initialization signal to the source of the driving transistor under the control of the first control signal and the second control signal; during a second stage, storing, by the reset compensation module, the threshold voltage for the driving transistor in the storage module under the control of the first control signal; and during a third stage, writing, by the data writing module, the data signal into the first end of the storage module under the control of the third control signal.

In a possible implementation, the driving method provided by the embodiments of the present disclosure further comprises: during a fourth stage, driving, by the driving transistor, the light emitting device to emit light under the control of the storage module.

Correspondingly, the embodiments of the present disclosure further provide an organic electroluminescent display panel, comprising any of the above pixel circuits provided by the embodiments of the present disclosure.

Correspondingly, the embodiments of the present disclosure further provide a display device, comprising any of the above organic electroluminescent display panels provided by the embodiments of the present disclosure.

In the pixel circuit, driving method thereof and related devices provided by the embodiments of the present disclosure, the pixel circuit comprises: a reset compensation module, a data writing module, a storage module and a driving transistor. With the cooperation of each module, the is pixel circuit can compensate shift of a threshold voltage for a driving transistor by storing the threshold voltage for the driving transistor in the storage module. Therefore, when the source of the driving transistor in the pixel circuit is connected with a light emitting device for driving it to emit light for display, the driving current of the driving transistor for driving the light emitting device to emit light will be only associated with the voltage of the data signal, but not the threshold voltage for the driving transistor. In this way, influence of the threshold voltage for the driving transistor on the light emitting device will be avoided. In other words, when same data signals are loaded into different pixel units, images with a same luminance can be obtained and thereby evenness of the image luminance in display regions of the display device is improved.

### BRIEF DESCRIPTION OF DRAWINGS

FIG. 1 is a schematic structural view for a 2T1C pixel circuit in the prior art;

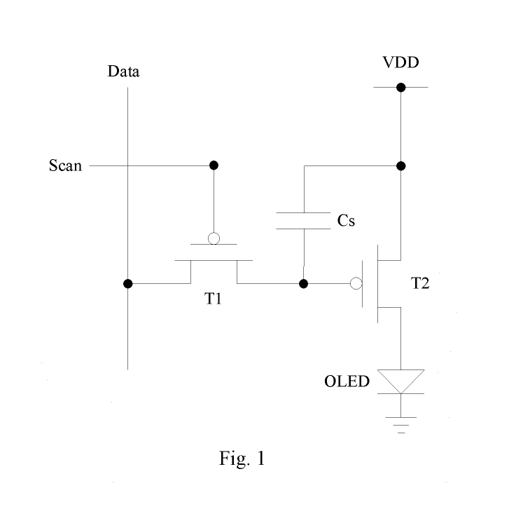

FIG. 2 is a schematic structural view for a pixel circuit provided by the embodiments of the present disclosure;

FIG. 3a is a schematic structural view for a specific pixel circuit provided by the embodiments of the present disclosure;

FIG. 3b is a schematic structural view for another specific pixel circuit provided by the embodiments of the present disclosure;

FIG. 4a is a schematic timing view for the pixel circuit as shown in FIG. 3a;

FIG. 4b is a schematic timing view for the pixel circuit as shown in FIG. 3b; and

FIG. 5 is a flow chart of a driving method for a pixel circuit provided by the embodiments of the present disclosure.

### DETAILED DESCRIPTION OF EMBODIMENTS

The specific embodiments of the pixel circuit, the driving method thereof and related devices provided by the embodiments of the present is disclosure are explained as follows in detail with reference to the drawings.

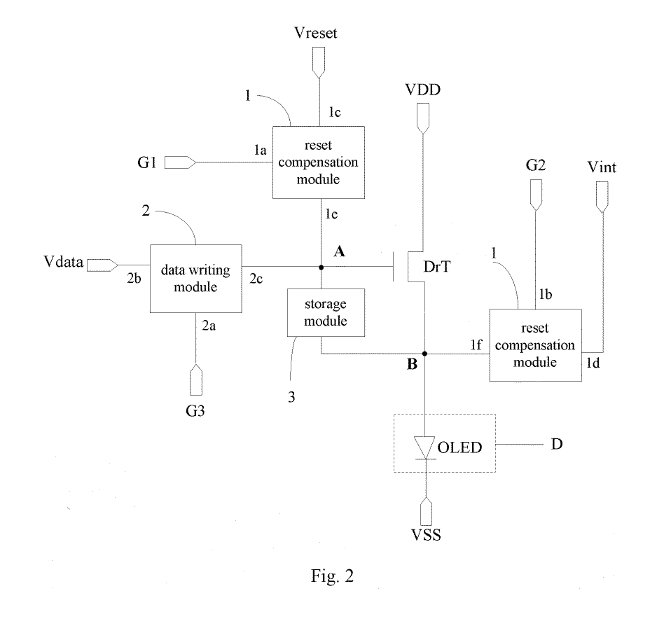

As shown in FIG. 2, the pixel circuit provided by the embodiments of the present disclosure comprises: a reset compensation module 1, a data writing module 2, a storage module 3 and a driving transistor DrT.

A drain of the driving transistor DrT is connected with a first reference signal terminal VDD; a gate thereof is connected with a first end of the storage module 3, a first output end 1e of the reset compensation module 1 and an output end 2c of the data writing module 2 respectively; and a source thereof is connected with a second output end 1f of the reset compensation module 1 and a second end of the storage module 3 respectively.

A first input end 1a of the reset compensation module 1 is used for receiving a first control signal G1, a second input end 1b thereof is used for receiving a second control signal G2, a third input end 1c thereof is used for receiving a reset signal Vreset and a fourth input end 1d thereof is used for receiving an initialization signal Vint. The reset compensation module 1 is further configured for: during a first stage, providing the reset signal Vreset to the gate of the driving transistor DrT and the initialization signal

Vint to the source of the driving transistor DrT under the control of the first control signal G1 and the second control signal G2; and during a second stage, storing a threshold voltage Vₜₕ for the driving transistor DrT in the storage module 3 under the control of the first control signal G1.

A first input end 2a of the data writing module 2 is used for receiving a third control signal G3 and a second input end 2b thereof is used for receiving a data signal Vdata. The data writing module 2 is further configured for: during a third stage, writing the data signal Vdata into the first end of the storage module 3 under the control of the third control signal G3.

Furthermore, the pixel circuit provided by the embodiments of the present disclosure further comprises a light emitting device D. One end of the light emitting device D is connected with the source of the driving transistor DrT, and the other end thereof is connected with a second reference signal terminal VSS.

Furthermore, the driving transistor DrT is further configured for: during a fourth stage, driving the light emitting device D to emit light under the control of the storage module 3.

The pixel circuit provided by the embodiments of the present disclosure comprises: a reset compensation module, a data writing module, a storage module and a driving transistor. With the cooperation of each module, the pixel circuit can compensate shift of a threshold voltage for a driving transistor by storing the threshold voltage for the driving transistor in the storage module. Therefore, when the source of the driving transistor in the pixel circuit is connected with a light emitting device for driving it to emit light for display, the driving current of the driving transistor for driving the light emitting device to emit light will be only associated with the voltage of the data signal, but not the threshold voltage for the driving transistor. In this way, influence of the threshold voltage for the driving transistor on the light emitting device will be avoided. In other words, when same data signals are loaded into different pixel units, images with a same luminance can be obtained and thereby evenness of the image luminance in display regions of the display device is improved.

The present disclosure will be explained in detail as follows in combination with a specific embodiment. It should be noted that the embodiment is provided for better explaining the present disclosure, instead of limiting it.

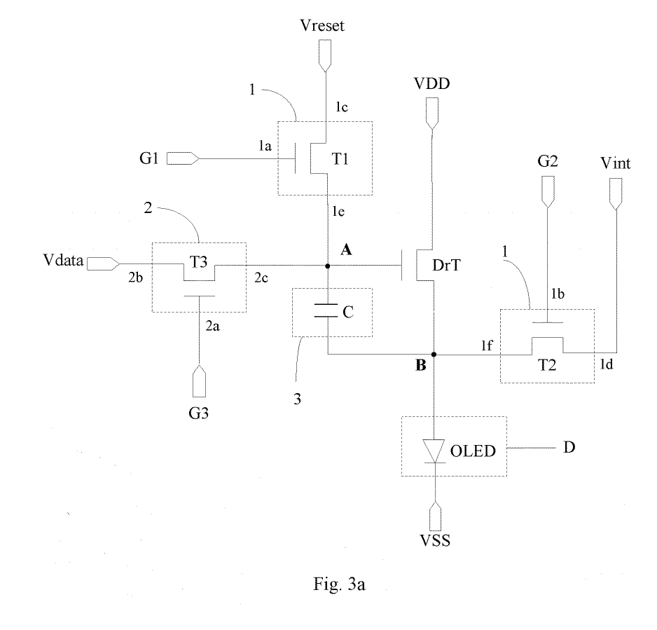

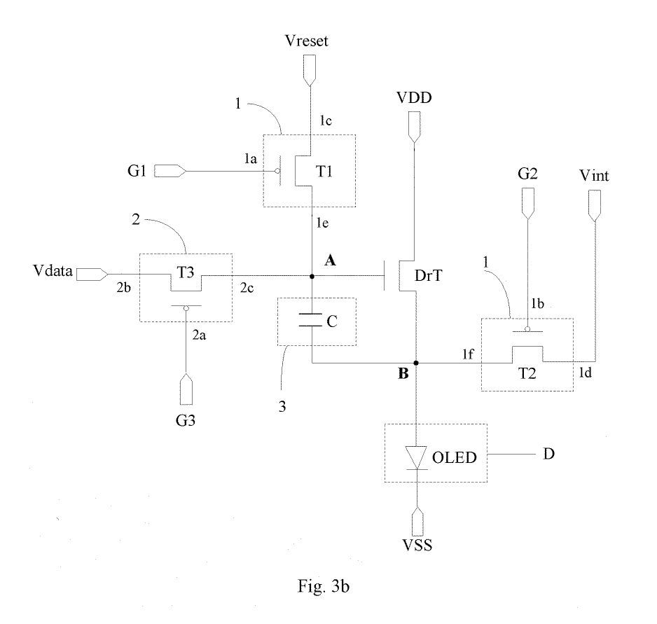

In specific implementations, in the pixel circuit provided by the embodiments of the present disclosure, as shown in FIGS. 3a and 3b, the driving transistor DrT can be either an N-type transistor or a P-type transistor, which will not be limited here.

The pixel circuit provided by the embodiments of the present disclosure will be explained in detail in the following text by taking the driving transistor being an N-type transistor as an example.

Specifically, in the pixel circuit provided by the embodiments of the present disclosure, as shown in FIGS. 3a and 3b, the driving transistor DrT is an N-type transistor. In this case, in order to ensure that the driving transistor can operate normally, the voltage of the corresponding first reference signal terminal VDD is generally a positive voltage, and the second reference signal terminal VSS is generally grounded or the voltage thereof is a negative value.

Furthermore, in specific implementations, the light emitting device D in the pixel circuit provided by the embodiments of the present disclosure is generally an organic light emitting diode OLED. As shown in FIGS. 3a and 3b, the anode of the organic light emitting diode OLED is connected with the source of the driving transistor DrT, and the cathode thereof is connected with the second reference voltage source VSS. The organic light emitting diode OLED emits light for display with the help of the saturation current of the driving transistor DrT.

The present disclosure will be explained in detail as follows in combination with a specific embodiment. It should be noted that the embodiment is provided for better explaining the present disclosure, instead of limiting it.

Optionally, in the pixel circuit provided by the embodiments of the present disclosure, as shown in FIGS. 3a and 3b, the reset compensation module 1 comprises: a first switching transistor T1 and a second switching transistor T2. A gate of the first switching transistor T1 is the first input end 1a of the reset compensation module 1, a source thereof is the third input end 1c of the reset compensation module 1 and a drain thereof is the first output end 1e of the reset compensation module 1. A gate of the second switching transistor T2 is the second input end 1b of the reset compensation module 1, a source thereof is the fourth input end 1d of the reset compensation module 1 and a drain thereof is the second output end 1f of the reset compensation module 1.

Furthermore, in specific implementations, as shown in FIG. 3a, the first switching transistor T1 can be an N-type transistor. In this case, when the first control signal G1 is high, the first switching transistor T1 is in an ON state. On the contrary, when the first control signal G1 is low, the first switching transistor T1 is in an OFF state. Alternatively, as shown in FIG. 3b, the first switching transistor T1 can also be a P-type transistor. In this case, when the first control signal G1 is low, the first switching transistor T1 is in an ON state. On the contrary, when the first control signal G1 is high, the first switching transistor T1 is in an OFF state. No limitation will be made here.

Furthermore, in specific implementations, as shown in FIG. 3a, the second switching transistor T2 can be an N-type transistor. In this case, when the second control signal G2 is high, the second switching transistor T2 is in an ON state. On the contrary, when the second control signal G2 is low, the second switching transistor T2 is in an OFF state. Alternatively, as shown in FIG. 3b, the second switching transistor T2 can also be a P-type transistor. In this case, when the second control signal G2 is low, the second switching transistor T2 is in an ON state. On the contrary, when the second control signal G2 is high, the second switching transistor T2 is in an OFF state. No limitation will be made here.

Optionally, in order to simplify the manufacture process, in the pixel circuit provided by the embodiments of the present disclosure, as shown in FIG. 3a, the first switching transistor T1 and the second switching transistor T2 are both N-type transistors. Alternatively, as shown in FIG. 3b, the first switching transistor T1 and the second switching transistor T2 are both P-type transistors. No limitation will be made here.

Specifically, for the pixel circuit provided by the embodiments of the present disclosure, during a first stage, the first switching transistor and the second switching transistor are both in an ON state under the control of the first control signal and the second control signal respectively. In this case, The reset signal is provided to the gate of the driving transistor by the first switching transistor which is switched on, and the initialization signal is provided to the source of the driving transistor by the second switching transistor which is switched on, such that the gate voltage of the driving transistor becomes Vreset, and the source voltage becomes Vint+V_{A} (wherein V_{A} is a voltage drop between the voltage V_{DD} of the first reference signal terminal VDD and the Vint). During a second stage, the first switching transistor is in an ON state under the control of the first control signal. In this case, the gate voltage of the driving transistor is still maintained at Vreset, and the driving transistor is switched on, such that a voltage difference between the gate of the driving transistor and the source thereof is retained at V_{th,} i.e., the voltage difference across the storage module is held at Vₜₕ. In this way, the threshold voltage Vₜₕ for the driving transistor is stored in the storage module and the source voltage of the driving transistor turns from Vint+V_{A} into Vreset−Vₜₕ.

It should be noted that, in the pixel circuit provided by the embodiments of the present disclosure, the reset signal and the initialization signal need to satisfy Vreset<Vint+V_{A}. The reason for this is that only when the driving transistor is in an ON state during the first stage, can the voltage difference between the gate of the driving transistor and the source thereof be retained at Vₜₕ during the second stage, so as to store the threshold voltage Vₜₕ for the driving transistor in the storage module.

What is mentioned above only explains a specific structure of the reset compensation module in the pixel circuit by way of example. In specific implementations, the specific structure of the reset compensation module can further be other structures knowable for those skilled in the art, but not limited to the one provided by the embodiments of the present disclosure. No limitation will be made here.

Optionally, in the pixel circuit provided by the embodiments of the present disclosure, as shown in FIGS. 3a and 3b, the data writing module 2 comprises: a third switching transistor T3. A gate of the third switching transistor T3 is the first input end 2a of the data writing module 2, a source thereof is the second input end 2b of the data writing module 2 and a drain thereof is the output end 2c of the data writing module 2.

Furthermore, in specific implementations, as shown in FIG. 3a, the third switching transistor T3 can be an N-type transistor. In this case, when the third control signal G3 is high, the third switching transistor T3 is in an ON state. While conversely, when the third control signal G3 is low, the third switching transistor T3 is in an OFF state. Alternatively, as shown in FIG. 3b, the third switching transistor T3 can also be a P-type transistor. In this case, when the third control signal G3 is low, the third switching transistor T3 is in an ON state. While conversely, when the third control signal G3 is high, the third switching transistor T3 is in an OFF state. No limitation will be made here.

Specifically, for the pixel circuit provided by the embodiments of the present disclosure, during the third stage, the third switching transistor is in an ON state under the control of the third control signal. In this case, the data signal is written into the first end of the storage module by the third switching transistor which is switched on, such that the gate voltage of the driving transistor turns from Vreset into Vdata. Because of the storage module, the voltage difference across the storage module is still retained at Vₜₕ. Therefore, the source voltage of the driving transistor turns from Vreset−Vₜₕ into Vreset−Vₜₕ+α(Vdata−Vreset)+ΔV. In the formula above, α equals to Cel/(Cel+Cs), wherein Cel is an equivalent capacitance value of the light emitting device and Cs is a capacitance value of the capacitor C; and ΔV is a drain voltage on the driving transistor, which is mainly associated with an electron mobility u of the driving transistor. This means that the electron mobility of the driving transistor can be controlled by controlling the drain voltage on the driving transistor.

What is mentioned above only explains a specific structure of the data writing module in the pixel circuit by way of example. In specific implementations, the specific structure of the data writing module can further be other structures knowable for those skilled in the art, but not limited to the one provided by the embodiments of the present disclosure. No limitation will be made here.

Optionally, in the pixel circuit provided by the embodiments of the present disclosure, as shown in FIGS. 3a and 3b, the storage module 3 is a capacitor C. A first electrode plate of the capacitor C is the first end of the storage module 3, and a second electrode plate thereof is the second end of the storage module 3.

Specifically, for the pixel circuit provided by the embodiments of the present disclosure, during the first stage, the voltages for the two electrode plates of the capacitor are respectively Vreset and Vint+V_{A}. And during the second stage, the voltage difference between the two electrode plates of the capacitor becomes Vₜₕ. While during the third stage, the voltage for the first electrode plate of the capacitor jumps into Vdata, and according to the capacitive charge conservation law, the voltage for the second electrode plate of the capacitor will turn into Vreset−Vₜₕ+α(Vdata−Vreset)+ΔV at this time. Finally, during the fourth stage, the voltages for the two electrode plates of the capacitor are still maintained at the voltages during the third stage, and the driving transistor operates in a saturated state under the effect of the capacitor. As can be known from the current characteristics in a saturated state, an operating current I_{D} that flows through the driving transistor and functions to drive the light emitting device to emit light satisfies the following formula: I_{D}=½Ku(V_{gs}−Vₜₕ₁)²=½Ku[Vreset−Vₜₕ+α(Vdata−Vreset)+ΔV−Vdata−Vₜₕ]²=½Ku[(1−α)(Vdata−Vreset)−ΔV]². In the formula above, K is a structure parameter, u is an electron mobility of the driving transistor, and Ku is relatively stable in a same structure and hence can be regarded as a constant. As can be seen from the above formula, the operating current I_{D} of the light emitting device is no longer influenced by the threshold voltage Vₜₕ for the driving transistor, and is only associated with the data signal Vdata and the reset signal Vreset, but not the voltage for the first reference signal terminal VDD. In this way, both the shift of the threshold voltage Vₜₕ for the driving transistor due to the technique process and the long time operation, and the influence exerted by the IR Drop on the operating current I_{D} of the light emitting device D will be thoroughly eliminated, thereby improving the display unevenness of the panel.

It should be noted that the driving transistor and the switching transistors mentioned in the embodiments of the present disclosure can be either thin film transistors (TFT) or metal oxide semiconductor (MOS) field effect transistors, which will not be limited here.

Optionally, in order to simplify the manufacture process, in the pixel circuit provided by the embodiments of the present disclosure, the switching transistors are all P-type transistors or N-type transistors, which will not be limited here.

Further optionally, the driving transistor and the switching transistors mentioned in the embodiments of the present disclosure can be all designed as N-type transistors, which can simplify the manufacture process forthe pixel circuit.

The operation procedure of the pixel circuit provided by the embodiments of the present disclosure will be described as follows by taking the pixel circuits shown in FIGS. 3a and 3b as an example respectively. In order to facilitate the description, the gate of the driving transistor DrT is prescribed as a first node A, and the source of the driving transistor DrT is prescribed as a second node B. Besides, in the following description, 1 indicates a high level signal, and 0 indicates a low level signal.

To begin with, a first example will be described in the following.

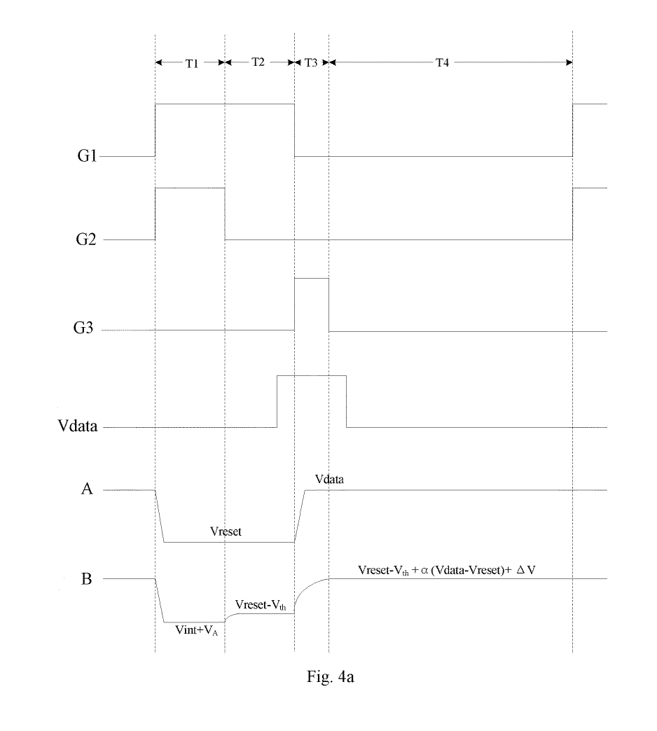

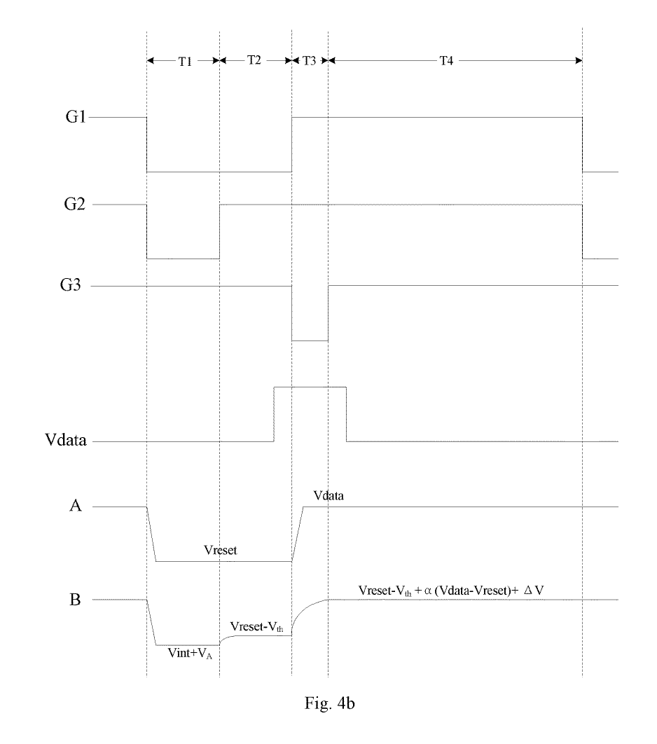

The operation procedure is described by taking the pixel circuit structure shown in FIG. 3a as an example. In the pixel circuit shown in FIG. 3a, the driving transistor and the switching transistors are all N-type transistors. The corresponding input timing chart is shown in FIG. 4a. Specifically, stages T1, T2, T3 and T4 in the input timing chart as shown in FIG. 4a are selected.

During the first stage T1, G1=1, G2=1, G3=0. In this case, the first switching transistor T1 and the second switching transistor T2 are both in an ON state, and the third switching transistor T3 is in an OFF state. The reset signal Vreset is provided to the gate of the driving transistor DrT by the first switching transistor T1 which is switched on, and the initialization signal Vint is provided to the source of the driving transistor DrT by the second switching transistor T2 which is switched on. Then, the gate voltage (i.e., the voltage for the first node A) of the driving transistor DrT becomes Vreset, and the source voltage (i.e., the voltage for the second node B) becomes Vint+V_{A}, wherein V_{A} is a voltage drop between the voltage V_{DD} for the first reference signal terminal VDD and the Vint.

During the second stage T2, G1=1, G2=0, G3=0. In this case, the first switching transistor T1 is in an ON state, and the second switching transistor T2 and the third switching transistor T3 are both in an OFF state.

The voltage for the first node A is still maintained at Vreset, and the driving transistor DrT is switched on. Then, a voltage difference between the gate of the driving transistor DrT and the source thereof is retained at Vₜₕ, i.e., the voltage difference across the capacitor C is held at Vₜₕ. In this way, the threshold voltage Vₜₕ for the driving transistor DrT is stored in the capacitor C and the voltage for the second node B turns from Vint+V_{A} into Vreset−Vₜₕ.

During the third stage T3, G1=0, G2=0, G3=1. In this case, the third switching transistor T3 is in an ON state, and the first switching transistor T1 and the second switching transistor T2 are both in an OFF state. The data signal Vdata is written into the first electrode plate of the capacitor C by the third switching transistor T3 which is switched on, such that the voltage for the first node A turns from Vreset into Vdata. According to the capacitive charge conservation law, the voltage for the second electrode plate of the capacitor C jumps into Vreset−Vₜₕα(Vdata−Vreset)+ΔV, which turns the voltage for the second node B from Vreset−Vₜₕ into Vreset−Vₜₕ+α(Vdata−Vreset)+ΔV. In the formula above, α equals to Cel/(Cel+Cs), wherein Cel is an equivalent capacitance value of the OLED and Cs is a capacitance value of the capacitor C; and ΔV is a drain voltage on the driving transistor, which is mainly associated with an electron mobility u of the driving transistor. This means that the electron mobility of the driving transistor can be controlled by controlling the drain voltage on the driving transistor.

During the fourth stage T4, G1=0, G2=0, G3=0. In this case, the voltages for the two electrode plates of the capacitor C are still maintained at the voltages during the third stage, and the driving transistor DrT operates in a saturated state under the effect of the capacitor C. As can be known from the current characteristics in a saturated state, an operating current I_{OLED} that flows through the driving transistor DrT and functions to drive the OLED to emit light satisfies the following formula: I_{OLED}=½Ku(V_{gs}−Vₜₕ₁)²=½Ku[Vreset−Vₜₕ+α(Vdata−Vreset)+ΔV−Vdata−Vₜₕ]²=½Ku[(1−α)(Vdata−Vreset)−ΔV]² . In the formula above, K is a structure parameter, u is an electron mobility of the driving transistor DrT, and Ku is relatively stable in a same structure and hence can be regarded as a constant.

As can be seen from the above formula, the operating current I_{OLED} of the OLED is no longer influenced by the threshold voltage Vₜₕ for the driving transistor DrT, and is only associated with the data signal Vdata and the reset signal Vreset, but not the voltage for the first reference signal terminal VDD. In this way, both the shift of the threshold voltage Vₜₕ for the driving transistor due to the technique process and the long time operation, and the influence exerted by the IR Drop on the operating current I_{OLED} of the OLED will be thoroughly eliminated, thereby improving the display unevenness of the panel.

In addition, the wave forms for driving signals of a pixel circuit in the prior art are usually very complicated, since both positive voltage pulse signals and negative voltage pulse signals are included, and even complex multi-pulse signals and band pulse signals are also included in some occasions. In this case, the design for a GOA (gate on array) circuit with an N-type TFT is very difficult. At present, in order to simplify the design for a GOA circuit with an N-type TFT, the pixel circuit are designed into a structure where the driving signals are all single positive voltage pulse signals. However, an existing pixel circuit like this generally comprises a plurality of TFTs and requires a plurality of driving signals, which is detrimental to the promotion of yield. However, as can be known from the above embodiments, the pixel circuit provided by the present disclosure has a simple structure, and moreover the driving signals (G1, G2 and G3) are all single positive voltage pulse signals.

Next, a second example will be described as follows.

The operation procedure is described by taking the pixel circuit structure shown in FIG. 3b as an example. In the pixel circuit shown in FIG. 3b, the driving transistor and the switching transistors are all N-type transistors. The corresponding input timing chart is shown in FIG. 4b. Specifically, stages T1, T2, T3 and T4 in the input timing chart as shown in FIG. 4b are selected.

During the first stage T1, G1=0, G2=0, G3=1. In this case, the first switching transistor T1 and the second switching transistor T2 are both in an ON state, and the third switching transistor T3 is in an OFF state. The reset signal Vreset is provided to the gate of the driving transistor DrT by the first switching transistor T1 which is switched on, and the initialization signal Vint is provided to the source of the driving transistor DrT by the second switching transistor T2 which is switched on. Then, the gate voltage (i.e., the voltage for the first node A) of the driving transistor DrT becomes Vreset, and the source voltage (i.e., the voltage for the second node B) becomes Vint+V_{A}, wherein V_{A} is a voltage drop between the voltage V_{DD} of the first reference signal terminal VDD and the Vint.

During the second stage T2, G1=0, G2=1, G3=1. In this case, the first switching transistor T1 is in an ON state, and the second switching transistor T2 and the third switching transistor T3 are both in an OFF state. The voltage for the first node A is still retained at Vreset, and the driving transistor DrT is switched on. Then, a voltage difference between the gate of the driving transistor DrT and the source thereof is maintained at Vₜₕ, i.e., the voltage difference across the capacitor C is held at Vₜₕ. In this way, the threshold voltage Vₜₕ for the driving transistor DrT is stored in the capacitor C and the voltage for the second node B turns from Vint+V_{A} into Vreset−Vₜₕ.

During the third stage T3, G1=1, G2=1, G3=0. In this case, the third switching transistor T3 is in an ON state, and the first switching transistor T1 and the second switching transistor T2 are both in an OFF state. The data signal Vdata is written into the first electrode plate of the capacitor C by the third switching transistor T3 which is switched on, such that the voltage for the first node A turns from Vreset to Vdata. According to the capacitive charge conservation law, the voltage for the second electrode plate of the capacitor C jumps into Vreset−Vₜₕ+α(Vdata−Vreset)+ΔV, which turns the voltage for the second node B from Vreset−Vₜₕ into Vreset−Vₜₕ+α(Vdata−Vreset)+ΔV. In the formula above, α is Cel/(Cel+Cs), wherein Cel is an equivalent capacitance value of the OLED and Cs is a capacitance value of the capacitor C; and ΔV is a drain voltage on the driving transistor, which is mainly associated with an electron mobility u of the driving transistor. This means that the electron mobility of the driving transistor can be controlled by controlling the drain voltage on the driving transistor.

During the fourth stage T4, G1=1, G2=1, G3=1. In this case, the voltages for the two electrode plates of the capacitor C are still maintained at the voltages during the third stage, and the driving transistor DrT operates in a saturated state under the effect of the capacitor C. As can be known from the current characteristics in a saturated state, an operating current I_{OLED} that flows through the driving transistor DrT and functions to drive the OLED to emit light satisfies the following formula: I_{OLED}=½Ku(V_{gs}−Vₜₕ₁)²=½Ku[Vreset−Vₜₕ+α(Vdata−Vreset)+ΔV−Vdata−Vₜₕ]²=½Ku[(1−α)(Vdata−Vreset)−ΔV]². In the formula above, K is a structure parameter, u is an electron mobility of the driving transistor DrT, and Ku is relatively stable in a same structure and hence can be regarded as a constant.

As can be seen from the above formula, the operating current I_{OLED} of the OLED is no longer influenced by the threshold voltage Vₜₕ for the driving transistor DrT, and is only associated with the data signal Vdata and the reset signal Vreset, but not the voltage for the first reference signal terminal VDD. In this way, both the shift of the threshold voltage Vₜₕ for the driving transistor due to the technique process and the long time operation, and the influence exerted by the IR Drop on the operating current I_{OLED} of the OLED will be thoroughly eliminated, thereby improving the display unevenness of the panel. In addition, the pixel circuit provided by the present disclosure has a simple structure, and moreover the driving signals (G1, G2 and G3) are all single negative voltage pulse signals.

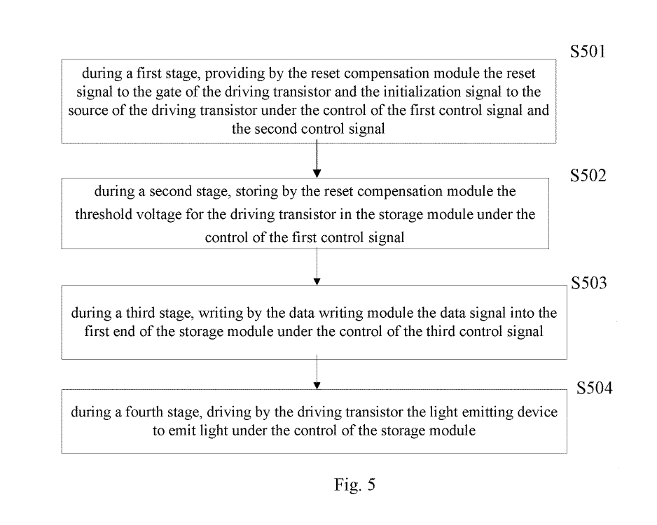

Based on the same inventive concept, the embodiments of the present disclosure further provide a driving method for any of the above pixel circuits. As shown in FIG. 5, the method comprises steps of: S501, during a first stage, providing by the reset compensation module the reset signal to the gate of the driving transistor and the initialization signal to the source of the driving transistor under the control of the first control signal and the second control signal; S502, during a second stage, storing by the reset compensation module the threshold voltage for the driving transistor in the storage module under the control of the first control signal; and S503, during a third stage, writing by the data writing module the data signal into the first end of the storage module under the control of the third control signal.

Furthermore, the driving method for the pixel circuit provided by the embodiments of the present disclosure further comprises the following step S504: during a fourth stage, driving by the driving transistor the light emitting device to emit light under the control of the storage module.

Based on the same inventive concept, the embodiments of the present disclosure further provide an organic electroluminescent display panel, comprising any of the pixel circuits provided by the embodiments of the present disclosure. Since the principle of the organic electroluminescent display panel for solving problems is similar to that of the aforementioned pixel circuit, for the implementation of the pixel circuit in the organic electroluminescent display panel, references can be made to the implementation of the pixel circuit in the aforementioned embodiments, which will not be repeated for simplicity.

Based on the same inventive concept, the embodiments of the present disclosure further provide a display device, comprising the organic electroluminescent display panel provided by the embodiments of the present disclosure. The display device can be a display, a handset, a television, a notebook, an integrated machine and so on. Other components necessary for the display device should be understood by a person having ordinary skills in the art, and hence will not be expounded for simplicity. This should not be taken as limitations to the present disclosure either.

In the pixel circuit, the driving method thereof and related devices provided by the embodiments of the present disclosure, the pixel circuit comprises: a reset compensation module, a data writing module, a storage module and a driving transistor. With the cooperation of each module, the pixel circuit can compensate shift of a threshold voltage for a driving transistor by storing the threshold voltage for the driving transistor in the storage module. Therefore, when the source of the driving transistor in the pixel circuit is connected with a light emitting device for driving it to emit light for display, the driving current of the driving transistor for driving the light emitting device to emit light will be only associated with the voltage of the data signal, but not the threshold voltage for the driving transistor. In this way, influence of the threshold voltage for the driving transistor on the light emitting device will be avoided. In other words, when same data signals are loaded into different pixel units, images with a same luminance can be obtained and thereby evenness of the image luminance in display regions of the display device is improved.

Obviously, those skilled in the art can make various modifications and variations to the present disclosure without deviating from the spirits and scopes of the present disclosure. Thus if the modifications and variations to the present disclosure fall within the scopes of the claims of the present disclosure and the equivalent techniques thereof, the present disclosure is intended to include them too.

1. A pixel circuit, comprising: a reset compensation module, a data writing module, a storage module and a driving transistor; wherein
a drain of the driving transistor is connected with a first reference signal terminal, a gate thereof is connected with a first end of the storage module, a first output end of the reset compensation module and an output end of the data writing module respectively, and a source thereof is connected with a second output end of the reset compensation module and a second end of the storage module respectively;
a first input end of the reset compensation module is used for receiving a first control signal, a second input end thereof is used for receiving a second control signal, a third input end thereof is used for receiving a reset signal and a fourth input end thereof is used for receiving an initialization signal;
the reset compensation module is further configured for: during a first stage, providing the reset signal to the gate of the driving transistor and the initialization signal to the source of the driving transistor under the control of the first control signal and the second control signal;
and during a second stage, storing a threshold voltage for the driving transistor in the storage module under the control of the first control signal;
a first input end of the data writing module is used for receiving a third control signal and a second input end thereof is used for receiving a data signal; and
the data writing module is further configured for: during a third stage, writing the data signal into the first end of the storage module under the control of the third control signal.

2. The pixel circuit according to claim 1, further comprising a light emitting device, wherein
one end of the light emitting device is connected with the source of the driving transistor, and the other end thereof is connected with a second reference signal terminal; and
the driving transistor is further configured for: during a fourth stage, driving the light emitting device to emit light under the control of the storage module.

3. The pixel circuit according to claim 1, wherein the reset compensation module comprises: a first switching transistor and a second switching transistor;
a gate of the first switching transistor is the first input end of the reset compensation module, a source thereof is the third input end of the reset compensation module and a drain thereof is the first output end of the reset compensation module; and
a gate of the second switching transistor is the second input end of the reset compensation module, a source thereof is the fourth input end of the reset compensation module and a drain thereof is the second output end of the reset compensation module.

4. The pixel circuit according to claim 1, wherein the data writing module comprises: a third switching transistor;
a gate of the third switching transistor is the first input end of the data writing module, a source thereof is the second input end of the data writing module and a drain thereof is the output end of the data writing module.

5. The pixel circuit according to claim 1, wherein the storage module is a capacitor;
a first electrode plate of the capacitor is the first end of the storage module, and a second electrode plate thereof is the second end of the storage module.

6. The pixel circuit according to claim 1, wherein the driving transistor is an N-type transistor.

7. The pixel circuit according to claim 6, wherein the switching transistors are all P-type transistors or N-type transistors.

8. A driving method for the pixel circuit according to claim 1, comprising:
during a first stage, providing, by the reset compensation module, the reset signal to the gate of the driving transistor and the initialization signal to the source of the driving transistor under the control of the first control signal and the second control signal;
during a second stage, storing, by the reset compensation module, the threshold voltage for the driving transistor in the storage module under the control of the first control signal; and
during a third stage, writing, by the data writing module, the data signal into the first end of the storage module under the control of the third control signal.

9. The driving method according to claim 8, wherein
the pixel circuit further comprises a light emitting device, one end of the light emitting device being connected with the source of the driving transistor, and the other end thereof being connected with a second reference signal terminal, and
the driving method further comprising:
during a fourth stage, driving, by the driving transistor, the light emitting device to emit light under the control of the storage module.

10. An organic electroluminescent display panel, comprising the pixel circuit according to claim 1.

11. A display device, comprising the organic electroluminescent display panel according to claim 10.

12. The organic electroluminescent display panel according to claim 10, wherein the pixel circuit further comprises a light emitting device;
one end of the light emitting device is connected with the source of the driving transistor, and the other end thereof is connected with a second reference signal terminal; and
the driving transistor is further configured for: during a fourth stage, driving the light emitting device to emit light under the control of the storage module.

13. The organic electroluminescent display panel according to claim 10, wherein the reset compensation module comprises: a first switching transistor and a second switching transistor;
a gate of the first switching transistor is the first input end of the reset compensation module, a source thereof is the third input end of the reset compensation module and a drain thereof is the first output end of the reset compensation module; and
a gate of the second switching transistor is the second input end of the reset compensation module, a source thereof is the fourth input end of the reset compensation module and a drain thereof is the second output end of the reset compensation module.

14. The organic electroluminescent display panel according to claim 10, wherein the data writing module comprises: a third switching transistor;
a gate of the third switching transistor is the first input end of the data writing module, a source thereof is the second input end of the data writing module and a drain thereof is the output end of the data writing module.

15. The organic electroluminescent display panel according to claim 10, wherein the storage module is a capacitor;
a first electrode plate of the capacitor is the first end of the storage module, and a second electrode plate thereof is the second end of the storage module.

16. The organic electroluminescent display panel according to claim 10, wherein the driving transistor is an N-type transistor.

17. The organic electroluminescent display panel according to claim 16, wherein the switching transistors are all P-type transistors or N-type transistors.
